(19) United States
(12) Patent Application Publication
(10) Pub. No.: US 2016/0135336 A1
(43) Pub. Date: May 12, 2016

(54) EMI SHIELDING STRUCTURE FOR ELECTRONIC COMPONENTS

(71) Applicant: ASIA VITAL COMPONENTS CO., LTD., New Taipei City (TW)

(72) Inventor: Chun-Ming Wu, New Taipei City (TW)

(21) Appl. No.: 14/538,821

(22) Filed: Nov. 12, 2014

(51) Int. Cl. H05K 9/00; H05K 7/20

(52) U.S. Cl. CPC H05K 9/0049; H05K 7/2039

(57) ABSTRACT

An EMI shielding structure for electronic components includes a cover body for enclosing and shielding at least one electronic component. The cover body includes a top section defining a chamber. A working fluid is contained in the chamber. At least one capillary structure is disposed in the chamber. One side of the top section faces the electronic component and is in contact with a top face of the electronic component. The EMI shielding structure can prevent the electronic component from electromagnetic wave interference. Also, the EMI shielding structure can enhance the heat dissipation efficiency for the electronic component.

### BACKGROUND OF THE INVENTION

1. Field of the Invention

The present invention relates generally to an anti-EMI structure, and more particularly to an EMI shielding structure for electronic components, which also has heat dissipation function.

2. Description of the Related Art

An electronic apparatus such as a mobile phone and a tablet generally includes many electronic components. In operation, the electronic components of the electronic apparatus will generate electromagnetic fields to a certain extent. The electromagnetic fields generated by the electronic components will interfere with and isolate each other to affect the normal operation of the electronic apparatus. Moreover, the electromagnetic wave will be radiated outward to harm human body. This phenomenon is so-called “electromagnetic interference” (EMI).

Currently, there are many means for avoiding EMI, including water galvanization, electroplating, vacuum sputtering and conductive paint spraying. Alternatively, a suitable metal-made electromagnetic shield can be directly added to outer side of the electronic component to shield the electromagnetic wave. The metal electromagnetic shield is manufactured at lower cost and meets the present environmental protection regulation. Therefore, the metal electromagnetic shield is most often used. The metal material of the electromagnetic shield structure is generally selected from a group consisting of stainless steel, aluminum foil, iron piece and aluminum-magnesium alloy. The electromagnetic shield is generally integrally formed as a shield body or cover body. The shield body has a top wall and a support skirt section perpendicularly extending from the periphery of the top wall. In use, the shield body is disposed on the electronic component to enclose or cover the electronic component and the skirt section is fixed on the circuit board by means of soldering or the like.

However, the conventional electromagnetic shield simply has electromagnetic wave shielding function. In practice, when the electronic component operates, the electronic component not only will generate electromagnetic wave, but also will generate heat. The heat will accumulate in the shield body and is hard to dissipate outward. Moreover, the heat conductivity of the metal-made electromagnetic shield structure is poor so that the electromagnetic shield body can hardly efficiently transfer the heat generated by the electronic component outward. As a result, the temperature will continuously rise to shorten the lifetime of the electronic component enclosed in the shield body or deteriorate the performance of the electronic component. Therefore, it has become a critical issue how to provide a best electromagnetic wave shielding effect and excellent heat dissipation effect at the same time.

### SUMMARY OF THE INVENTION

It is therefore a primary object of the present invention to provide an EMI shielding structure for electronic components, which can provide a best electromagnetic wave shielding effect and excellent heat dissipation efficiency at the same time.

It is a further object of the present invention to provide the above EMI shielding structure for electronic components, which includes a top section defining a chamber. At least one capillary structure is disposed in the chamber. A working fluid is contained in the chamber. Accordingly, the EMI shielding structure can provide excellent heat dissipation effect for the electronic component.

To achieve the above and other objects, the EMI shielding structure for electronic components of the present invention includes a cover body. The cover body has a top section defining a chamber. At least one capillary structure is disposed in the chamber. A working fluid is contained in the chamber. The top section is in contact with at least one electronic component.

In the above EMI shielding structure for electronic components, the top section has a board body and a cover board. The cover board is disposed on an upper side of the board body or disposed under a lower side of the board body. The board body and the cover board are spaced from each other. The chamber is defined between the board body and the cover board.

In the above EMI shielding structure for electronic components, the cover body further has a skirt section perpendicularly extending from the periphery of the top section to define a shielding space under the top section for receiving the electronic component.

In the above EMI shielding structure for electronic components, the cover board is positioned on the upper side of the board body. The board body is in contact with the electronic component.

In the above EMI shielding structure for electronic components, the cover board is positioned under the lower side of the board body. The cover board is in contact with the electronic component.

In the above EMI shielding structure for electronic components, the board body has multiple lateral edges. The lateral edges are downward bent to form the skirt section perpendicularly extending from the periphery of the top section.

In the above EMI shielding structure for electronic components, the top section and the skirt section are made of anti-EMI material including metal material.

In the above EMI shielding structure for electronic components, the cover body encloses multiple electronic components with different heights. The top section is formed with at least one raised section in accordance with the height of an electronic component with shorter height. The raised section is in contact with the electronic component with shorter height.

In the above EMI shielding structure for electronic components, the chamber is formed with a recessed section corresponding to the raised section of the top section.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1A is a perspective exploded view showing that the present invention is used to enclose and cover at least one electronic component;

FIG. 1B is an enlarged view of a circled area of FIG. 1A;

FIG. 1C is an enlarged view of another circled area of FIG. 1A;

FIG. 2A is a sectional view showing that the present invention is used to enclose and cover at least one electronic component;

FIG. 2B is an enlarged view of a circled area of FIG. 2A;

FIG. 3A is a sectional view of the present invention;

FIG. 3B is an enlarged view of a circled area of FIG. 3A;

FIG. 3C is a sectional view showing another embodiment of the capillary structure;

FIG. 4A is a sectional view showing that the present invention is used to enclose and cover multiple electronic components;

FIG. 4B is an enlarged view of a circled area of FIG. 4A;

FIG. 5A is a sectional view of another embodiment of the present invention;

FIG. 5B is an enlarged view of a circled area of FIG. 5A;

FIG. 6A is a sectional view showing that the other embodiment of the present invention is used to enclose and cover at least one electronic component;

FIG. 6B is an enlarged view of a circled area of FIG. 6A;

FIG. 6C is a sectional view showing another embodiment of the capillary structure;

FIG. 7A is a sectional view showing that the other embodiment of the present invention is used to enclose and cover multiple electronic components; and

FIG. 7B is an enlarged view of a circled area of FIG. 7A.

### DETAILED DESCRIPTION OF THE PREFERRED EMBODIMENTS

The embodiments of the present invention will be described hereinafter with reference to the drawings, wherein the same components are denoted with the same reference numerals.

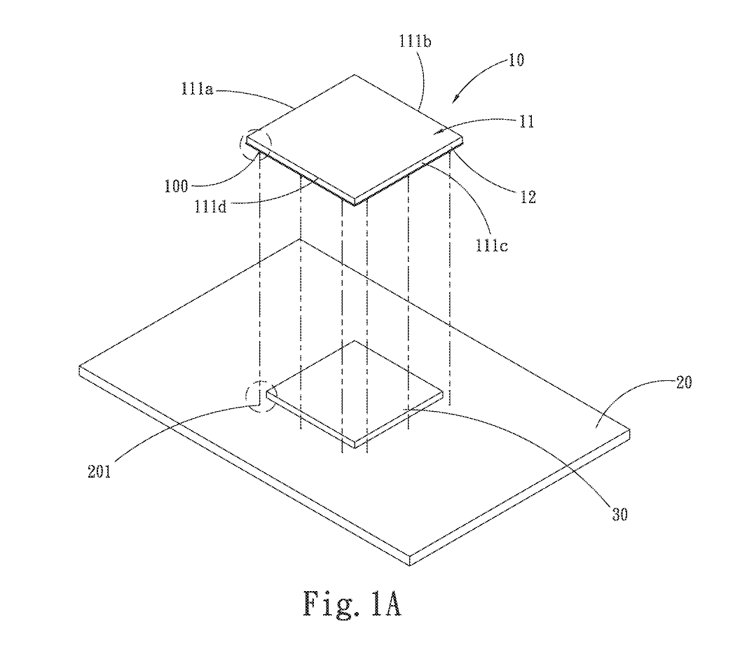

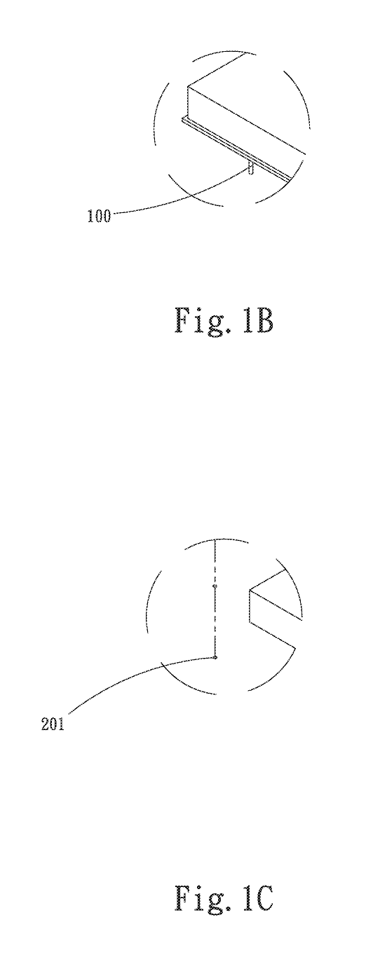

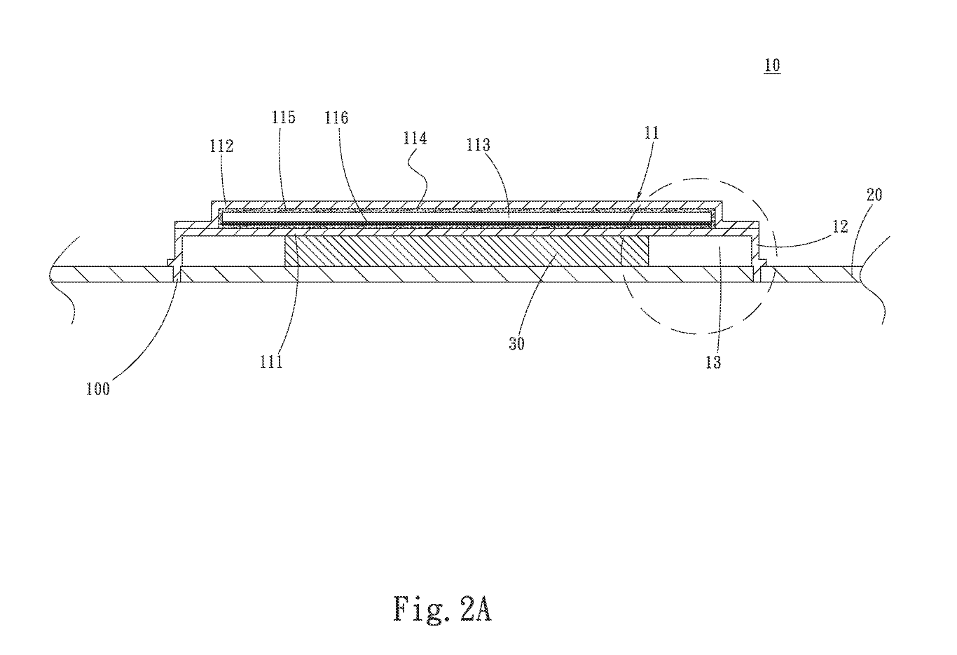

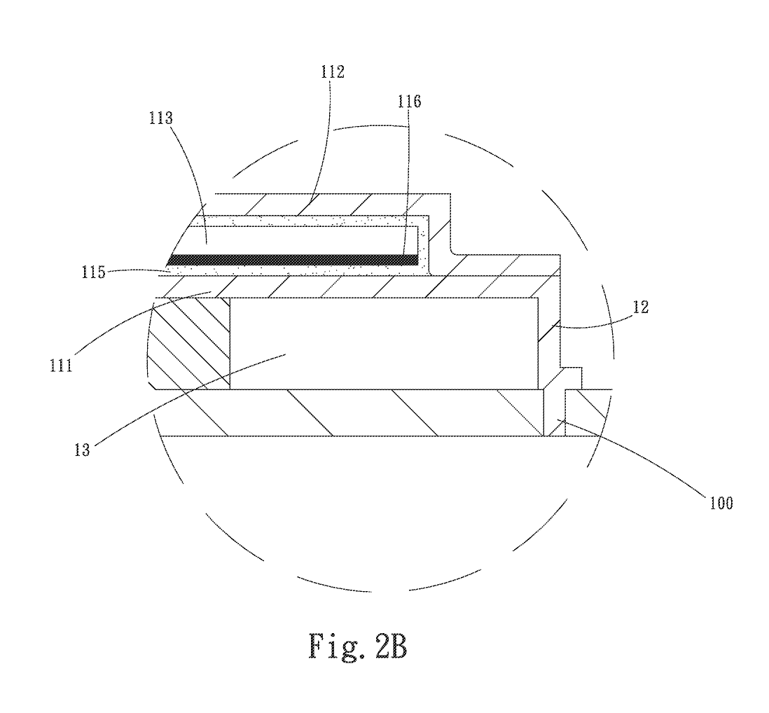

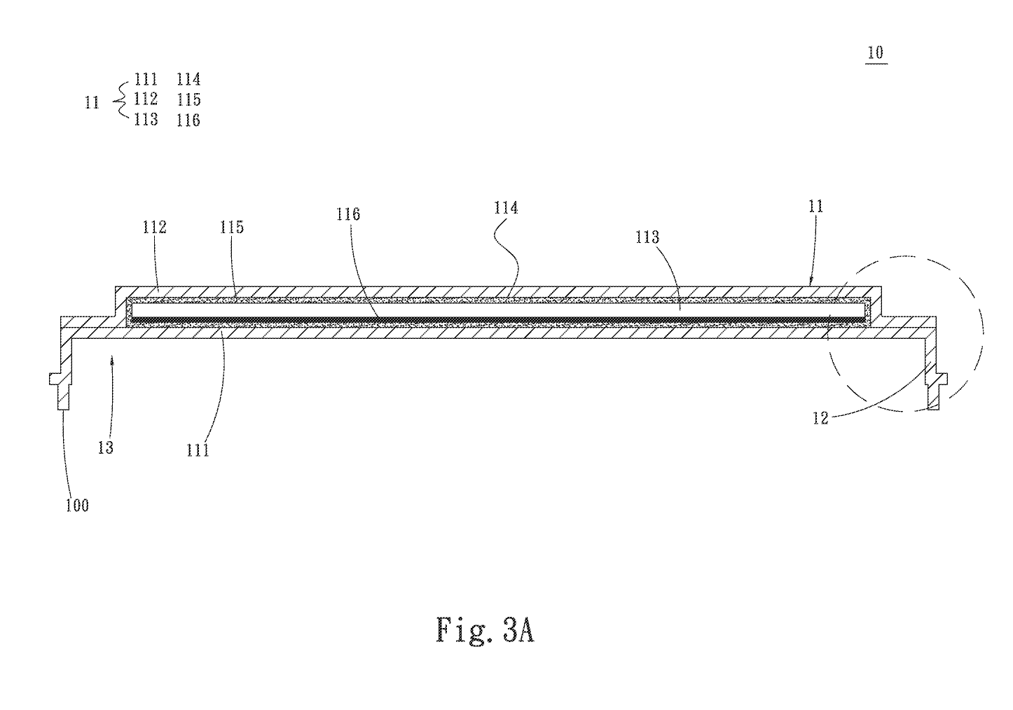

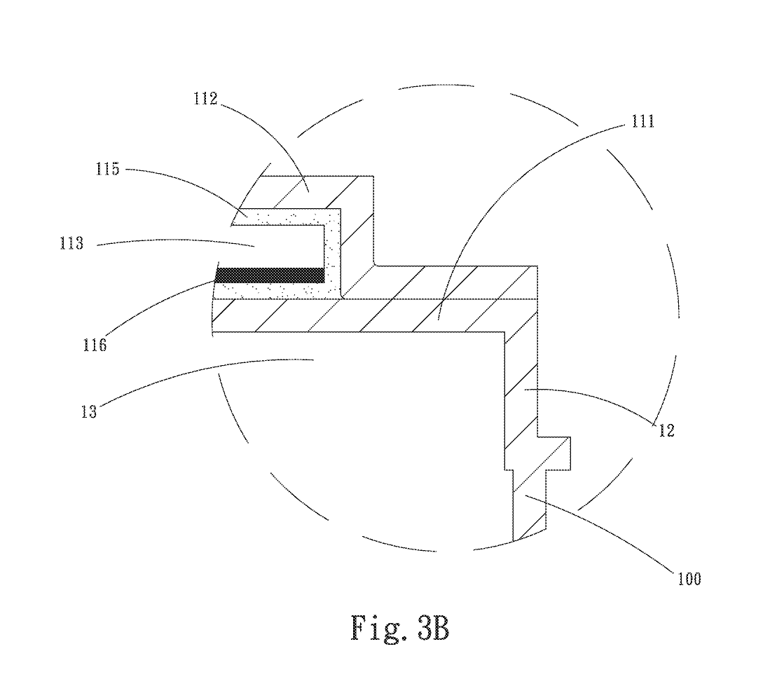

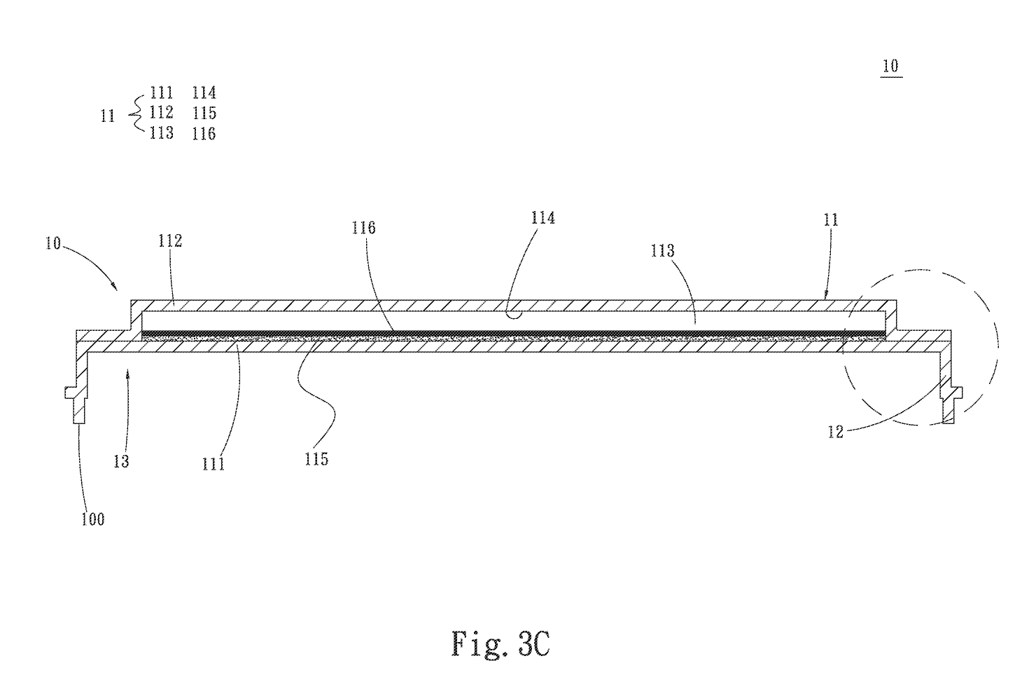

Please refer to FIGS. 1A to 3C. FIG. 1A is a perspective exploded view showing that the present invention is used to enclose and cover at least one electronic component. FIG. 1B is an enlarged view of a circled area of FIG. 1A. FIG. 1C is an enlarged view of another circled area of FIG. 1A. FIG. 2A is a sectional view showing that the present invention is used to enclose and cover at least one electronic component. FIG. 2B is an enlarged view of a circled area of FIG. 2A. FIG. 3A is a sectional view of the present invention. FIG. 3B is an enlarged view of a circled area of FIG. 3A. FIG. 3C is a sectional view showing another embodiment of the capillary structure. According to the drawings, the EMI shielding structure for electronic components of the present invention includes a cover body 10 for enclosing and covering at least one electronic component 30 on the circuit board 20 to shield electromagnetic wave of the electronic component 30. The bottom of the cover body 10 is formed with multiple grounding terminals 100. The circuit board 20 is formed with multiple grounding holes 201. The cover body 10 is soldered on the circuit board 20 with the grounding terminals 100 plugged in the grounding holes 201.

The cover body 10 includes a top section 11 and a skirt section 12 perpendicularly extending from a periphery of the top section 11. The top section 11 has a board body 111 and a cover board 112 spaced from each other. A chamber 113 is defined between the board body 111 and the cover board 112. The peripheries of the board body 111 and the cover board 112 are sealedly connected with each other. In this embodiment, the cover board 112 is disposed on upper side of the board body 111. Alternatively, in another embodiment (as described hereinafter), the cover board 112 is disposed under lower side of the board body 111. The board body 111 has multiple lateral edges 111a-111d. A capillary structure 115 is disposed in the chamber 113. A working fluid 116 is contained in the chamber 113.

After the chamber 113 is vacuumed, the working fluid 116 is filled into the chamber 113. The capillary structure 115 is, but not limited to, sintered metal powder formed on at least one inner wall 114 of the chamber 113. The capillary structure 115 is a porous structure for providing capillary attraction to drive the working fluid 116. In this embodiment, the capillary structure 115 is formed on upper and lower sides of the inner wall 114 of the chamber 113. Alternatively, in another embodiment as shown in FIG. 3C, the capillary structure 115 is only formed on the lower side of the inner wall 114 (the upper side of the board body 111). The working fluid 116 is selected from a group consisting of pure water, inorganic compound, alcohol group, ketone group, liquid metal, coolant, organic compound and a mixture thereof.

The skirt section 12 perpendicularly extends from the periphery of the top section 11 to define a shielding space 13 for receiving the electronic component 30. To speak more specifically, in this embodiment, the multiple lateral edges 111a-111d of the board body 111 are downward bent to form the skirt section 12 perpendicularly extending from the periphery of the top section 11. In another embodiment, the skirt section 12 is perpendicularly connected with the multiple lateral edges 111a-111d of the board body 111. The grounding terminals 100 are disposed at the free end of the skirt section 12 for fixing and grounding the cover body 10. The top section 11 and the skirt section 12 are made of anti-EMI material including metal material such as stainless steel, aluminum, iron or aluminum-magnesium alloy.

The board body 111 of the top section 11 faces the shielding space 13 as a heated side (or evaporation end) for absorbing the heat generated by the electronic component. The cover board 112 of the top section 11 contacts the environmental air as a heat dissipation side (condensation end) for transferring the heat absorbed by the board body 111 to the external environment and dissipate the heat.

As shown in FIG. 2A, after the cover body 10 encloses and shields the electronic component 30 on the circuit board 20, the electronic component 30 is received in the shielding space 13. The board body 111 of the top section 11 of the cover body 10 faces the electronic component 30 in contact with a top face of the electronic component 30. In operation, the electromagnetic wave generated by the electronic component 30 is isolated in the cover body 10. Especially, the electromagnetic wave generated by the electronic component 30 on the top face has a highest intensity. Therefore, the top section 11 of the cover body 10 is disposed on the top face of the electronic component 30 to achieve a best shielding effect for the electromagnetic wave generated by the electronic component 30. Also, the cover body 10 is able to shield the electronic component 30 from the electromagnetic wave generated by other electronic components outside the cover body 10 to avoid electromagnetic wave interference.

Furthermore, after the board body 111 absorbs the heat generated by the electronic component 30, the working fluid 116 in the chamber 113 is heated and evaporated into vapor to carry the heat to the cover board 112. When the vapor contacts the cover board 112, the heat is transferred to the environmental air and the vapor is condensed into liquid to go back to the board body 111 through the capillary structure 115. By means of phase change and vapor-liquid convection and circulation of the working fluid 116 in the chamber 113 between the board body 111 and the cover board 112 of the top section 11, the heat is quickly dissipated.

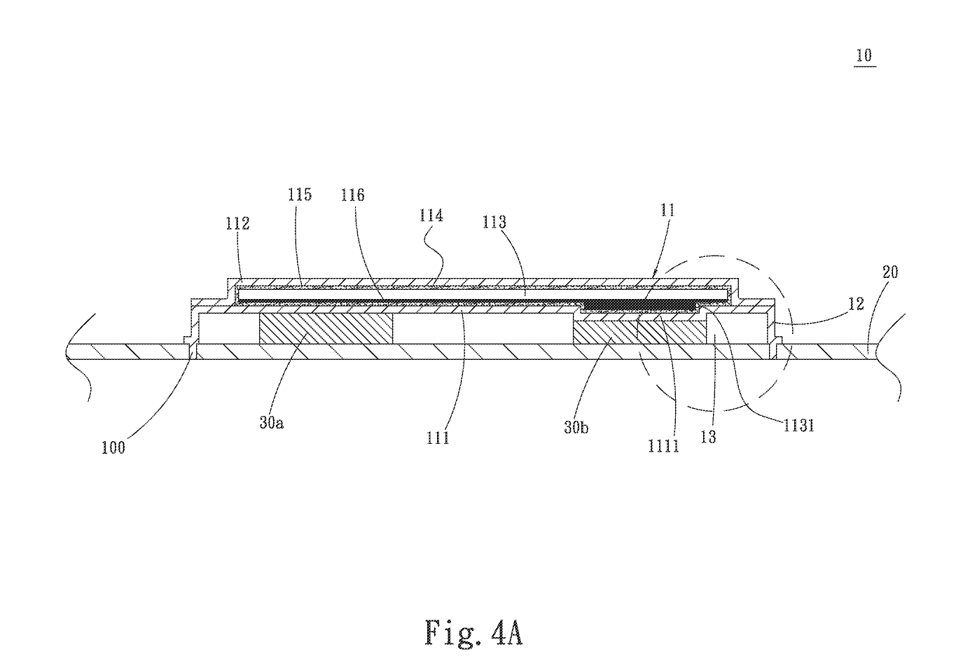

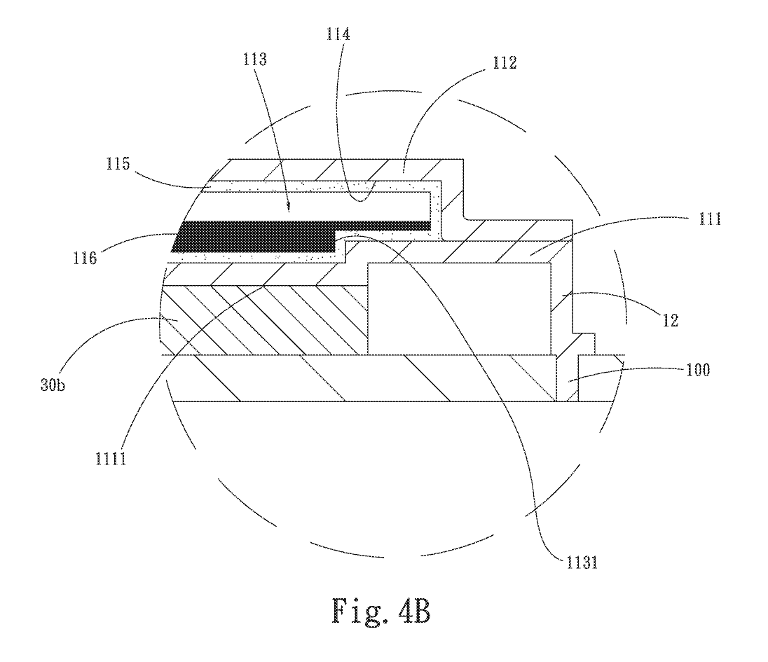

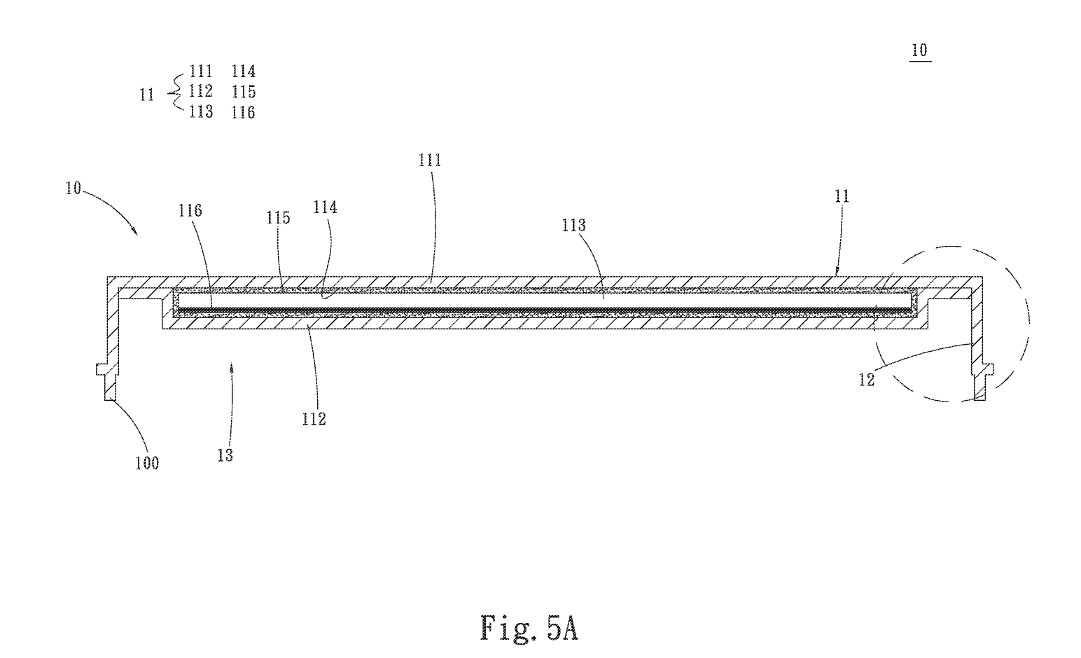

Please now refer to FIGS. 4A and 4B. FIG. 4A is a sectional view showing that the present invention is used to enclose and cover multiple electronic components. FIG. 4B is an enlarged view of a circled area of FIG. 4A. As shown in the drawings, the cover body 10 can be used to enclose and shield multiple electronic components on the circuit board 20, such as a first electronic component 30a and a second electronic component 30b to shield the electromagnetic wave of the first and second electronic components 30a, 30b. In this embodiment, the different electronic components have different heights. Therefore, the height of the board body 111 is varied with the position where the board body 111 covers the respective electronic components. For example, the board body 111 can be formed with a raised section corresponding to the shorter electronic component. The protrusion length of the raised section and the height of the electronic component are complementary to each other so that the raised section is in contact with the top face of the electronic component. The chamber 113 is formed with a recessed section corresponding to the raised section.

For example, as shown in the drawings, the first electronic component 30a has a height higher than a height of the second electronic component 30b. Therefore, a section of the board body 111 of the cover body 10 in alignment with the second electronic component 30b is formed with a raised section 1111. The raised section 1111 protrudes from the board body 111 to just abut against the top face of the second electronic component 30b. The chamber 113 is formed with a recessed section 1131 or a plane face in a position where the raised section 1121 is formed. By means of this structure, the heat generated by both the first and second electronic components 30a, 30b can be dissipated.

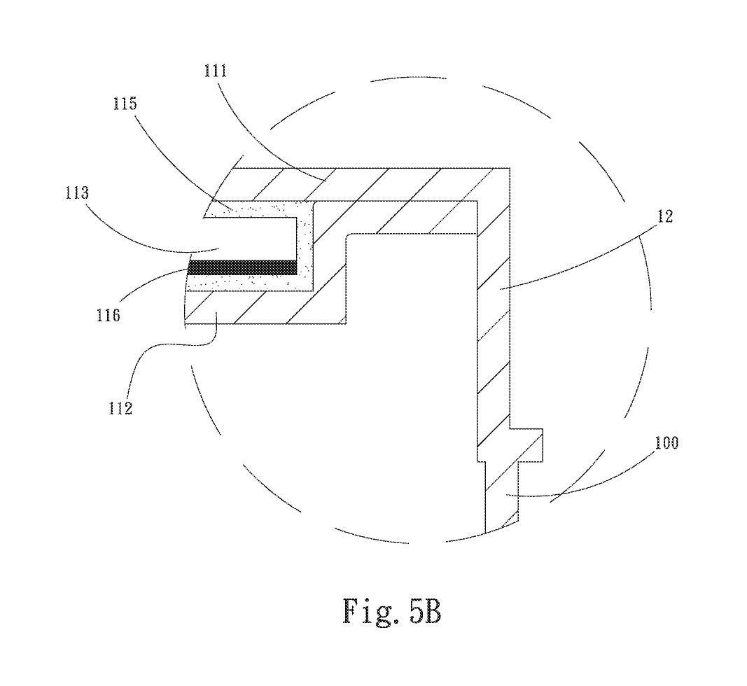

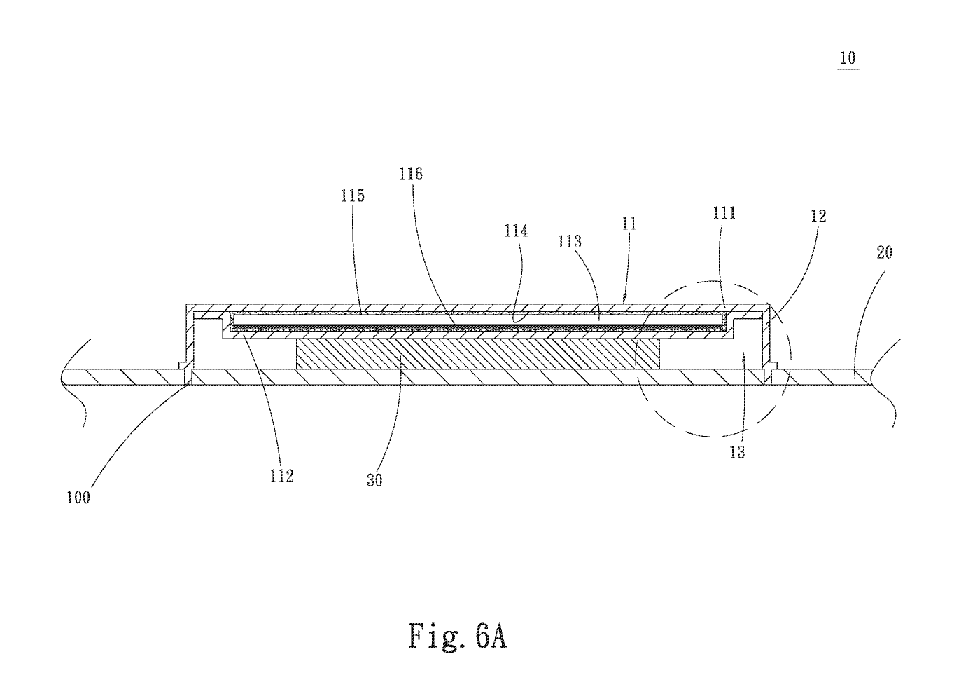

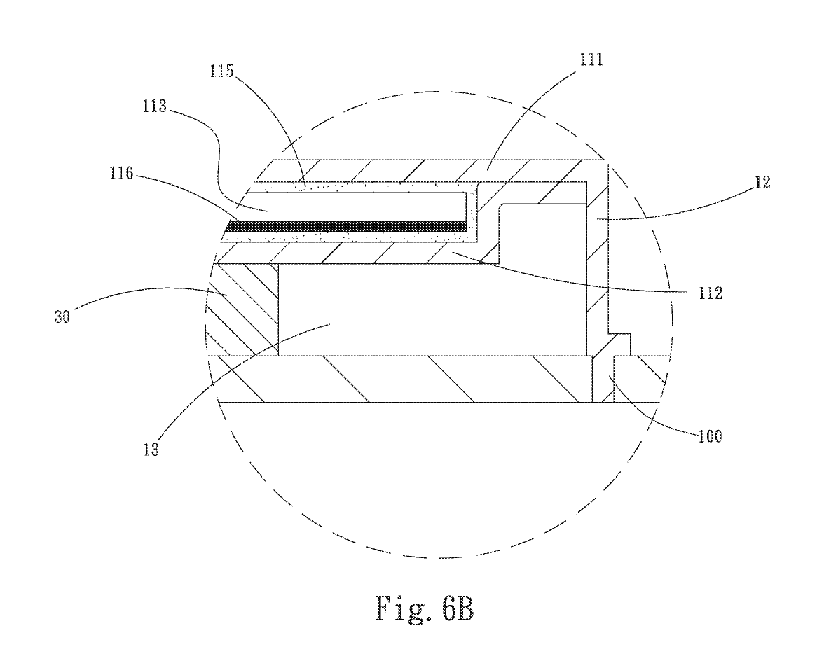

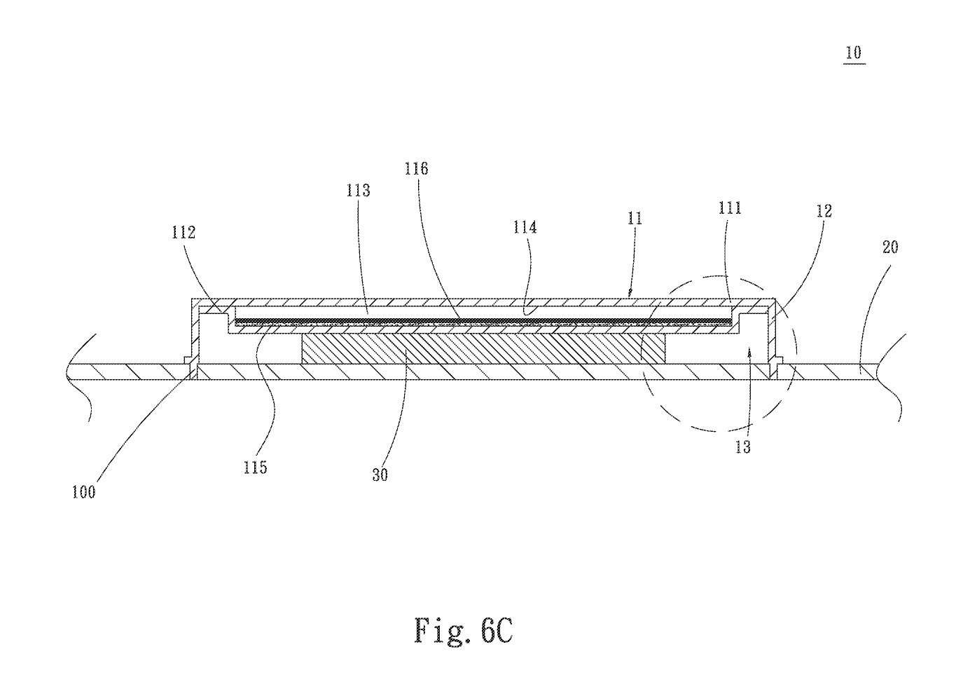

Please now refer to FIGS. 5A to 6C. FIG. 5A is a sectional view of another embodiment of the present invention. FIG. 5B is an enlarged view of a circled area of FIG. 5A. FIG. 6A is a sectional view showing that the other embodiment of the present invention is used to enclose and cover at least one electronic component. FIG. 6B is an enlarged view of a circled area of FIG. 6A. FIG. 6C is a sectional view showing another embodiment of the capillary structure. This embodiment is substantially identical to the above embodiment and the same components are denoted with the same reference numerals. This embodiment is different from the above embodiment in that the cover board 112 is disposed on the lower side of the board body 111. In this embodiment, the cover board 112 of the top section 11 faces the shielding space 13 as a heated side (or evaporation end) for absorbing the heat generated by the electronic component. The board body 111 of the top section 11 contacts the environmental air as a heat dissipation side (condensation end) for transferring the heat absorbed by the cover board 112 to the external environment and dissipate the heat.

As shown in FIG. 6A, after the cover body 10 encloses and shields the electronic component 30 on the circuit board 20, the electronic component 30 is received in the shielding space 13. The cover board 112 of the top section 11 of the cover body 10 faces the electronic component 30 in contact with a top face of the electronic component 30. The cover body 10 serves to shield the electromagnetic wave generated by the electronic component 30. Also, the heat generated by the electronic component 30 is transferred to the cover board 112. The working fluid 116 in the chamber 113 is heated and evaporated into vapor to carry the heat to the board body 111. When the vapor contacts the board body 111, the heat is transferred to the environmental air and the vapor is condensed into liquid to go back to the cover board 112 through the capillary structure 115. By means of phase change and vapor-liquid convection and circulation of the working fluid 116 in the chamber 113 between the cover board 112 and the board body 111 of the top section 11, the heat is quickly dissipated.

In this embodiment, the capillary structure 115 is formed on upper and lower sides of the inner wall 114 of the chamber 113. Alternatively, in another embodiment as shown in FIG. 6C, the capillary structure 115 is only formed on the lower side of the inner wall 114 (the upper side of the cover board 112).

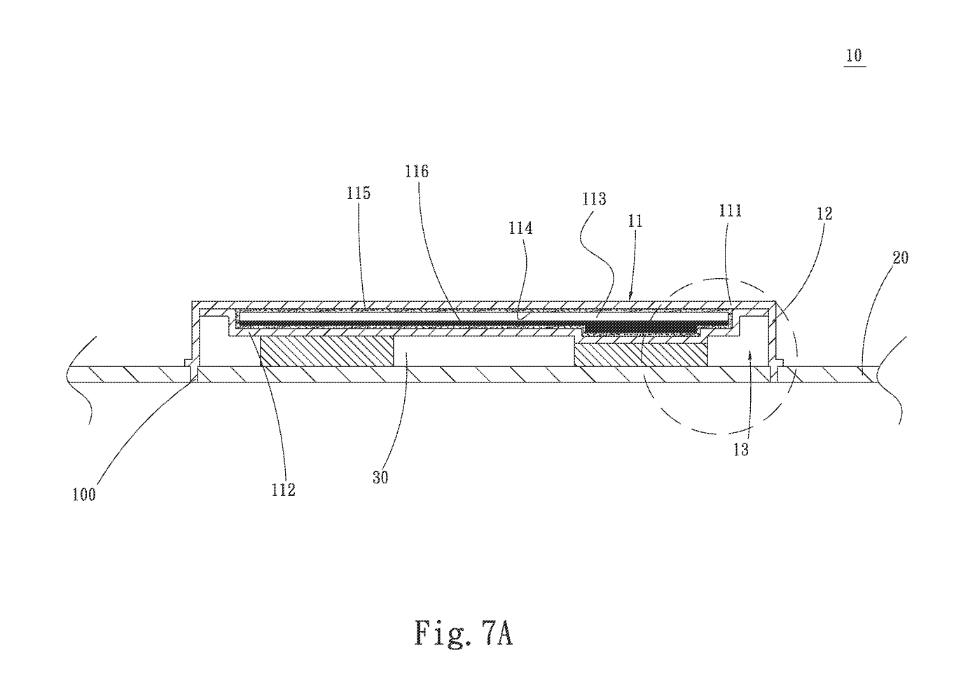

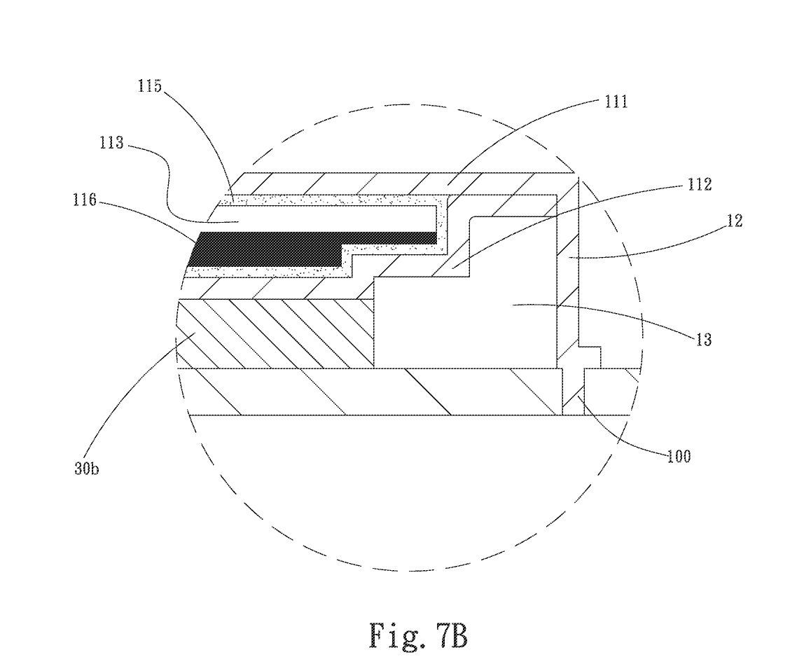

Please now refer to FIGS. 7A and 7B. FIG. 7A is a sectional view showing that the other embodiment of the present invention is used to enclose and cover multiple electronic components. FIG. 7B is an enlarged view of a circled area of FIG. 7A. As shown in the drawings, the cover body 10 can be also used to enclose and shield multiple electronic components on the circuit board 20 at one time.

In conclusion, the present invention can provide a best electromagnetic wave shielding effect. Also, the present invention can enhance the heat dissipation efficiency for the electronic component.

The present invention has been described with the above embodiments thereof and it is understood that many changes and modifications in the above embodiments can be carried out without departing from the scope and the spirit of the invention that is intended to be limited only by the appended claims.

What is claimed is:

1. An EMI shielding structure for electronic components for enclosing and shielding at least one electronic component, the EMI shielding structure comprising a cover body, the cover body including a top section and a skirt section perpendicularly extending from a periphery of the top section, the top section defining a chamber, at least one capillary structure being disposed in the chamber, a working fluid being contained in the chamber, the top section being in contact with the electronic component.

2. The EMI shielding structure for electronic components as claimed in claim 1, wherein the top section has a board body and a cover board, the cover board being disposed on an upper side of the board body or disposed under a lower side of the board body, the board body and the cover board being spaced from each other, the chamber being defined between the board body and the cover board.

3. The EMI shielding structure for electronic components as claimed in claim 2, wherein the skirt section perpendicularly extends from the periphery of the top section to define a shielding space under the top section for receiving the electronic component.

4. The EMI shielding structure for electronic components as claimed in claim 3, wherein the cover board is positioned on the upper side of the board body, the board body being in contact with the electronic component.

5. The EMI shielding structure for electronic components as claimed in claim 3, wherein the cover board is positioned under the lower side of the board body, the cover board being in contact with the electronic component.

6. The EMI shielding structure for electronic components as claimed in claim 4, wherein the top section is correspondingly in contact with multiple electronic components at the same time.

7. The EMI shielding structure for electronic components as claimed in claim 6, wherein the top section is formed with at least one raised section in accordance with different heights of the electronic components, the raised section being in contact with at least one electronic component with shorter height.

8. The EMI shielding structure for electronic components as claimed in claim 5, wherein the top section is correspondingly in contact with multiple electronic components at the same time.

9. The EMI shielding structure for electronic components as claimed in claim 8, wherein the top section is formed with at least one raised section in accordance with different heights of the electronic components, the raised section being in contact with at least one electronic component with shorter height.
